(19) United States
(12) Patent Application Publication
(10) Pub. No.: US 2014/0291681 A1
(43) Pub. Date: Oct. 2, 2014

(54) PHASE NOISE REDUCTION IN TRANSISTOR DEVICES

(71) Applicant: SKYWORKS SOLUTIONS, INC., Woburn, MA (US)

(72) Inventor: Stephen Joseph KOVACIC, Ottawa (CA)

(21) Appl. No.: 14/223,008

(22) Filed: Mar. 24, 2014

Related U.S. Application Data
(60) Provisional application No. 61/806,239, filed on Mar. 28, 2013.

(51) Int. Cl. H01L 29/735; H01L 29/04; H01L 29/66

(52) U.S. Cl. CPC H01L 29/735; H01L 29/6625; H01L 29/04
USPC 257/51; 438/341

(57) ABSTRACT

Semiconductor devices are disclosed having modified transistor dimensions configured to provide reduced phase noise in certain amplifier applications. Transistor devices having expanded emitter-poly overlap of the emitter window, which serves to separate the external base area from the lateral emitter-base junction, may experience a reduction of free electrons and holes that diffuse into the electric field of the emitter-base junction, thereby reducing phase noise.

### RELATED APPLICATION

This application claims the benefit of priority under 35 U.S.C. §119(e) of U.S. Provisional Application No. 61/806,239, filed on Mar. 28, 2013, and entitled “Phase Noise Reduction in Transistor Devices,” the disclosure of which is hereby incorporated by reference in its entirety.

### BACKGROUND

1. Field

The present disclosure generally relates to the field of electronics, and more particularly, to semiconductor devices.

2. Description of Related Art

Circuits and systems with time-based performance requirements can be affected by electrical noise from random fluctuation in electrical signals propagating in connected devices. For example, phase noise, such as that experienced by an electronic oscillator, can interfere with the performance of electronic devices. Phase noise in certain timing-dependent devices can be caused by self-phase noise of one or more active transistor devices.

### SUMMARY

Certain embodiments disclosed herein provide a semiconductor die including a bulk silicon substrate of a first impurity type having an upper surface that lies in a first plane and an epitaxial collector layer of a second impurity type having an upper surface that lies in a second plane substantially parallel to the first plane, the epitaxial collector layer being disposed between the first plane and the second plane. The semiconductor die may further include an oxide trench disposed between the first and second planes and a base layer of the first impurity type including an monosilicon portion disposed above the collector layer, a polysilicon portion disposed above the oxide trench, and a polysilicon/monosilicon boundary portion disposed laterally between the monosilicon portion and the polysilicon portion of the base layer. In certain embodiments, the semiconductor die further includes a metal contact in direct electrical communication with the base layer and disposed above the polysilicon portion, an emitter layer of the second impurity type disposed at least partially above the base layer and including a window portion in direct contact with the monosilicon portion of the base layer, and an emitter oxide layer in direct physical contact with the base layer and disposed laterally between the emitter window portion and the metal contact, the emitter oxide layer abutting the emitter window laterally at an emitter-oxide interface.

The lateral distance between the oxide trench and the emitter-oxide interface may advantageously be greater than approximately 0.4 μm. For example, the lateral distance between the oxide trench and the emitter-oxide interface may be approximately 0.5 μm. In certain embodiments, the lateral distance between the polysilicon/monosilicon boundary portion of the base layer and a depletion region of the base layer is greater than approximately 0.05 μm.

The lateral distance between the polysilicon/monosilicon boundary portion of the base layer and the depletion region of the base layer may be approximately 0.1 μm. In certain embodiments, the width of the emitter oxide layer is greater than approximately 0.2 μm. The width of the emitter oxide layer is between approximately 0.2-0.4 μm. For example, the width of the emitter oxide layer may be approximately 0.3 μm.

Certain embodiments disclosed herein provide a process of manufacturing a semiconductor die. The process may include providing a bulk silicon substrate of a first impurity type having an upper surface that lies in a first plane and disposing an epitaxial collector layer of a second impurity type having an upper surface that lies in a second plane substantially parallel to the first plane between the first plane and the second plane. In certain embodiments, the process further includes forming an oxide trench between the first and second planes and disposing a monosilicon portion of a base layer of the first impurity type above the collector layer and a polysilicon portion of the base layer above the oxide trench, the base layer including a polysilicon/monosilicon boundary portion laterally situated between the monosilicon portion and the polysilicon portion of the base layer. The process may further include disposing a metal contact in direct electrical communication with the base layer above the polysilicon portion and disposing an emitter layer of the second impurity type at least partially above the base layer and including a window portion in direct contact with the monosilicon portion of the base layer. In certain embodiments, the process includes disposing an emitter oxide layer in direct physical contact with the base layer laterally between the emitter window portion and the metal contact, the emitter oxide layer abutting the emitter window laterally at an emitter-oxide interface.

The lateral distance between the oxide trench and the emitter-oxide interface may advantageously be greater than approximately 0.4 μm. For example, the lateral distance between the oxide trench and the emitter-oxide interface may be approximately 0.5 μm. In certain embodiments, the lateral distance between the polysilicon/monosilicon boundary portion of the base layer and a depletion region of the base layer is greater than approximately 0.05 μm.

The lateral distance between the polysilicon/monosilicon boundary portion of the base layer and the depletion region of the base layer may be approximately 0.1 μm. In certain embodiments, the width of the emitter oxide layer is greater than approximately 0.2 μm. The width of the emitter oxide layer is between approximately 0.2-0.4 μm. For example, the width of the emitter oxide layer may be approximately 0.3 μm.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 illustrates a cross-sectional view of an embodiment of a bipolar transistor.

FIG. 2 illustrates a close-up cross-sectional view of a portion of the bipolar transistor of FIG. 1.

FIG. 3 illustrates a close-up cross-sectional view of a portion of the bipolar transistor of FIG. 1.

FIG. 4 illustrates a cross-sectional view of an embodiment of a bipolar transistor.

FIG. 5 illustrates a close-up cross-sectional view of a portion of a SiGe bipolar transistor.

FIG. 6 illustrates a block diagram of an embodiment of an oscillator circuit in accordance with one or more features of the present disclosure.

FIG. 7 illustrates a schematic diagram of an embodiment of a dielectric resonator oscillator in accordance with one or more features of the present disclosure.

FIG. 8 illustrates a block diagram of an example parallel feedback oscillator topology in accordance with one or more features of the present disclosure.

FIG. 9 illustrates a block diagram of an example series feedback oscillator topology in accordance with one or more features of the present disclosure.

FIG. 10 illustrates an embodiment of an RF module in accordance with one or more features of the present disclosure.

FIG. 11 is a block diagram showing an embodiment of a wireless device in accordance with one or more features of the present disclosure.

### DETAILED DESCRIPTION

Disclosed herein are example configurations and embodiments relating to transistor devices having reduced phase noise characteristics. With respect to active transistor devices, phase noise involves random fluctuation in the phase of signals propagating through such devices. Phase noise in oscillators or other circuit systems with time-based performance requirements can be a particular concern. As electronic device specifications increase data throughput requirements, modulations including decreased phase noise oscillators and lower-distortion transistor amplifiers may be necessary or desirable.

Residual phase noise for Si bipolar amplifiers operating in the linear region can be at least partially attributable to flicker noise generators within such devices. Flicker noise is electronic noise having a 1/f power density spectrum. Therefore, flicker noise is generally greater in lower-frequency applications. However, in electronic oscillator applications, low-frequency phase noise can be mixed up to frequencies close to the carrier frequency, thereby resulting in oscillator phase noise.

With respect to oscillator applications, it may therefore be desirable to utilize high-quality piezoelectric resonators in order to reduce noise. However, for crystal oscillators, dielectric resonator oscillators (DRGs), and other resonators comprising relatively high dielectric constants and low dissipation factors, cost considerations may make use of such components prohibitive or undesirable in certain applications. As an alternative, oscillator applications may advantageously incorporate RC or LC oscillator circuits, which include passive devices in a feedback configuration. Because such oscillator circuits generally are lower-Q devices compared to crystal, dielectric resonator, or other higher-Q devices (e.g., surface acoustic wave (SAW) oscillators), reducing phase noise may be a more significant concern.

Sources of electrical noise in semiconductor transistors can include one or more of the following: (1) shot noise caused by emission of electrons, photons, or passage of carriers across potential barriers; (2) thermal noise caused by carrier collisions with the semiconductor lattice; (3) partition noise caused by the splitting of carrier or photon current; and (4) generation-recombination flicker noise caused by the generation and recombination of hole-electron pairs. Certain embodiments disclosed herein provide mechanisms for reducing generation-recombination noise in Si and/or SiGe bipolar amplifiers, which may be of concern in oscillator applications. Generation-recombination noise may be up-converted through the phase variation of the amplifier phase response by the variation of the device parameters (C(bc), C(be), g(m), r(e)) caused by the recombination 1/f noise.

As described in greater detail below, modified transistor dimensions can provide a reduction in phase noise in certain amplifier applications. As an example, NPN bipolar transistors suitable for microwave amplifiers can include a base-emitter junction that comprises a diffusion of n-type dopant from the emitter into the p-type base. Such diffusion generally includes both a vertical and a lateral component. Laterally, the emitter-base junction may abut a dielectric material on one side (e.g., surface side). In order to reduce 1/f noise, it may be desirable to remove traps, crystal defects and/or other sources of free electrons and holes from the area in which they might diffuse towards the emitter-base junction. Therefore, expanding the emitter poly overlap of the emitter window serves to separate the external base area from the lateral emitter-base junction, as described herein, can contribute to the reduction of free electrons and holes in a transistor amplifier that diffuse into the electric field of the emitter-base junction.

### SEMICONDUCTOR DEVICE STRUCTURE

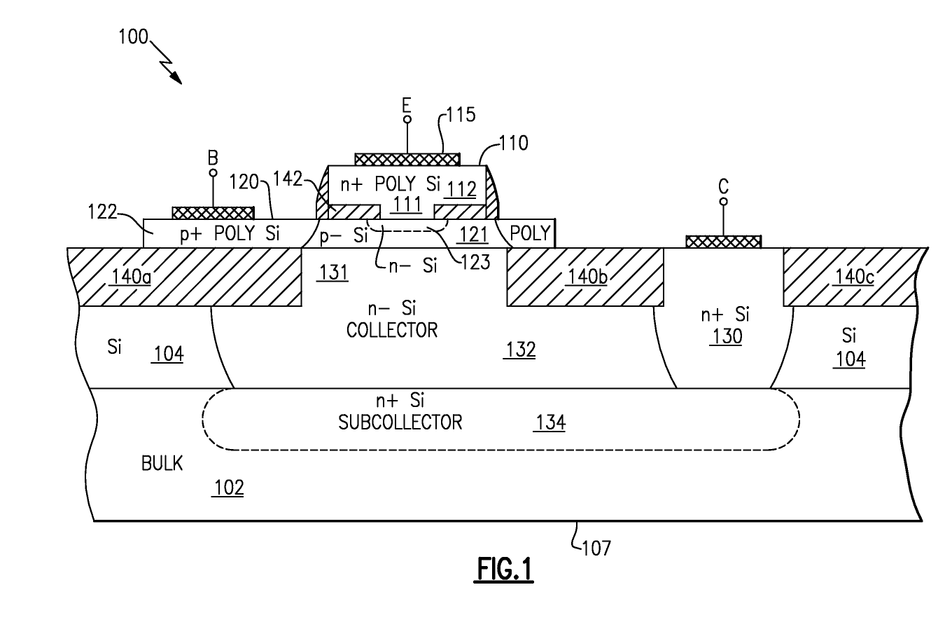

FIG. 1 illustrates a cross-section of a bipolar transistor device. While the illustrated device is an NPN bipolar transistor, principles described herein may be applicable to other transistor configurations, such as PNP transistors, or FET transistors. In certain embodiments, the device 100 includes a polysilicon emitter 110 with a metal contact 115 for transmission of electrical signals therefrom. The device 100 may be configured to operate at relatively high speeds, such as for microwave applications (e.g., approximately 25 GHz or greater at a V_{ce} of approximately 2V). For operation at microwave frequencies, it may be desirable for transistor dimensions to be relatively small compared to lower-frequency applications in order to improve speed by shortening the distance signals must travel within the device and to reduce, as much as possible, parasitic capacitances and junction capacitances. However, as described in greater detail below, shorter lateral dimensions, such as the distance between the heavily doped external base region and the emitter-base junction, can contribute to phase noise of the device.

Devices like that shown in FIG. 1 may be fabricated using a bulk silicon substrate 102 with a layer of epitaxial silicon 104 grown thereon. The silicon layer 104 includes an extrinsic collector region 130 which is heavily doped with n-type impurities (or p-type for a PNP device). The device 100 further includes a lightly doped collector region 132, as well as a heavily doped sub-collector region 134. In certain embodiments, the silicon layer 104 is intrinsic, or nearly undoped, outside of the illustrated collector portions.

Portions of the silicon substrate may be masked using a photolithographic process in order to allow for oxide deposition or growth 140 therein. The device 100 may include a p-type base region 120 above the collector region 132. As shown, at least a portion of the base 120 may lie above an oxide layer. The portion of the base 120 that lies above the oxide layer may be primarily polysilicon deposit since there is no underlying crystal structure upon which epitaxial Si or SiGe alloy might grow, whereas single-crystal silicon may be grown above the single-crystal collector region 132. The polysilicon region 122 is heavily doped, whereas the single-crystal region 121 may be generally intrinsic or doped as required during the epitaxial deposition.

The n-type emitter (or p-type for PNP devices) and an additional oxide layer 142 are formed above the base 120 to define the emitter window. In certain embodiments, the emitter is heavily doped n-type. A depletion region 123 may form within the base-emitter junction and extend into the base layer due to the high concentration of impurities in the emitter, which can out-diffuse down into the base layer. The proximity of the p+polysilicon base region to the depletion region 123 can contribute to phase noise generation in the device. Free carriers (e.g., holes) released from traps or other crystalline complexes from the polysilicon base region 122 can be absorbed by carriers (e.g., electrons) passing between the emitter 110 and the collector 132 through the depletion region 123, thereby causing flicker noise. Therefore, as the location and size of the polysilicon layer can be at least partially determined by relative placement of the oxide region 140a, in certain embodiments, a bipolar transistor is designed using an oxide mask configured to provide expanded lateral spacing between the oxide 140a and the crystalline region 111 of the emitter.

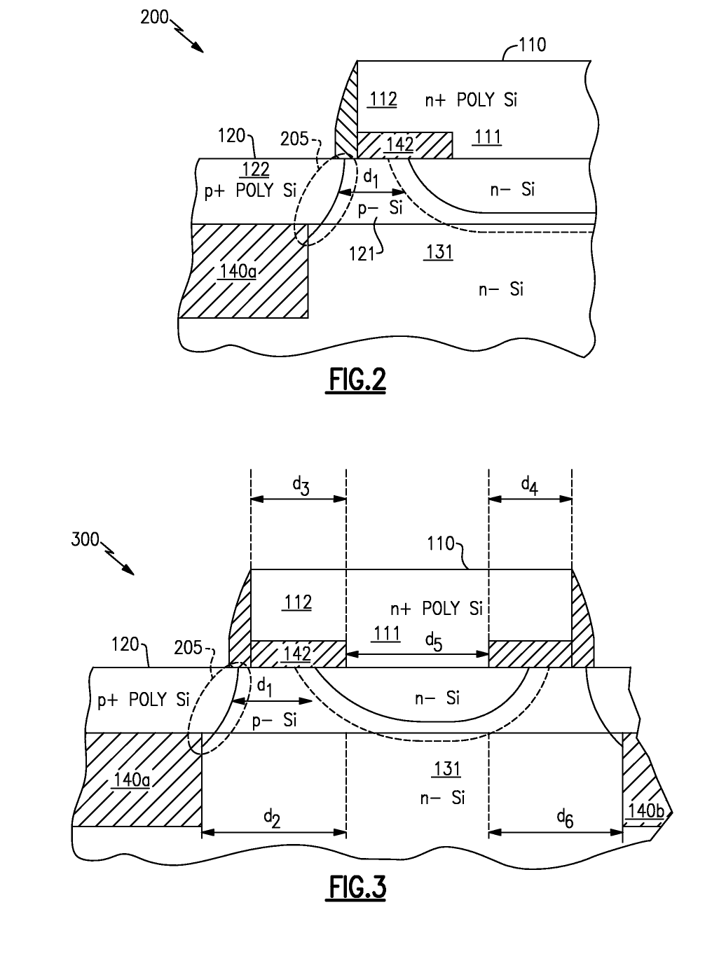

FIG. 2 illustrates a close-up view of a region of the device 100 shown in FIG. 1. The depicted region includes a portion of the base 120 including the polysilicon/monosilicon boundary 205 of the base. The region 205 is a transition region from the p+polysilicon 122 to the adjacent monosilicon 121, where the material transitions from polysilicon grains to a single-crystal type structure. In certain embodiments, the region 205 contains traps and/or defects that give rise to 1/f noise, as described above. The base-emitter junction may be formed when a diffusion of n-type emitter dopant moves into the p-type base. Such diffusion includes both vertical and lateral components. With respect to lateral diffusion, the emitter-base junction abuts a dielectric material 142 disposed on a surface of the base 120 during fabrication

The emitter 110 includes a polycrystalline region 112 disposed above the oxide layer 142, as well as a crystalline region 111, where n-type dopants have diffused downwards into the base. In certain embodiments, a Si/SiO2 interface may surround the emitter 110. The figure further shows the oxide layer 140a, which may be deposited and structured to define the active collector region 131.

The area of the base between the depletion region of the base-emitter interface and the extrinsic polysilicon base region 122 may contain traps, crystal defects, and/or other sources of free electrons and holes that are released and recaptured randomly or with a time signature, which can contribute to generation-recombination in the base. In certain embodiments, by increasing the distance d₁ between the emitter-base junction and the polysilicon base region 122 and, in particular, the boundary region 205, the effect of such sources of free electrons and/or holes can be reduced. The location and structure of the oxide layers 140, 142 can at least partially determine the distance d₁.

FIG. 3 illustrates a region similar to that illustrated in FIG. 2, wherein the various physical distances are called out in order to illustrate certain relevant physical dimensions of the device with respect to phase noise. As mentioned above, phase noise in the device 300 may be at least partially dependent on the distance dl between the emitter-base junction and the polysilicon/monosilicon boundary region of the base. The distance d₁ may be determined by one or more factors. For example, the relative lateral position of the oxide layer 140a to the crystalline region 111 of the emitter window may contribute to the value of the distance d₁. Therefore, if the oxide layer 140a is laterally extended out relative to the position of the emitter-base junction, the distance may be increased. By so doing, the area of the collector-base junction may be increased as well, which may affect device performance by increasing the collector-base capacitance and reducing the high-frequency performance of the transistor amplifier. In an embodiment, the value of distance d₁ is approximately 0.1 μm.

Increasing the relative lateral distance between the oxide layer 140a and the crystalline emitter region 111 may be achieved in a number of ways. For example, the oxide region 142 may be expanded laterally away from the center of the emitter 110. In certain embodiments, the width d₃ of the polysilicon region 112 of the emitter, defined by the width of the oxide layer 142, is greater than about 0.2 μm, such as between 0.2-0.4 μm. In certain embodiments, the distance d₃ is about 0.3 μm, or greater. In comparison with a width d₃ of about 0.2 μm, a width of about 0.3 μm may provide improvement in phase noise levels. The width d₃ may be controlled at least in part during device fabrication through masking of the oxide layer 142 and the emitter poly mask

The distance d₁ may also be expanded through expanding the lateral width of the active collector region 131, with respect to the portion of the collector beneath the oxide layer 142 and extending to the oxide layer 140a, as identified by the distance d₂. In an embodiment, the value of distance d₂ is approximately 0.5 μm

In certain embodiments, the distances d₃ and d₂ are greater on the base side of the emitter than are corresponding emitter/collector distances d₄ and d₆ on the collector side of the emitter, as illustrated. For example the ratio of distance d₃ to distance d₄ may be approximately 1.5:1. Furthermore, the ratio of distance d₂ to distance d₆ may likewise be greater than 1:1, and may be about 1.5:1, or greater.

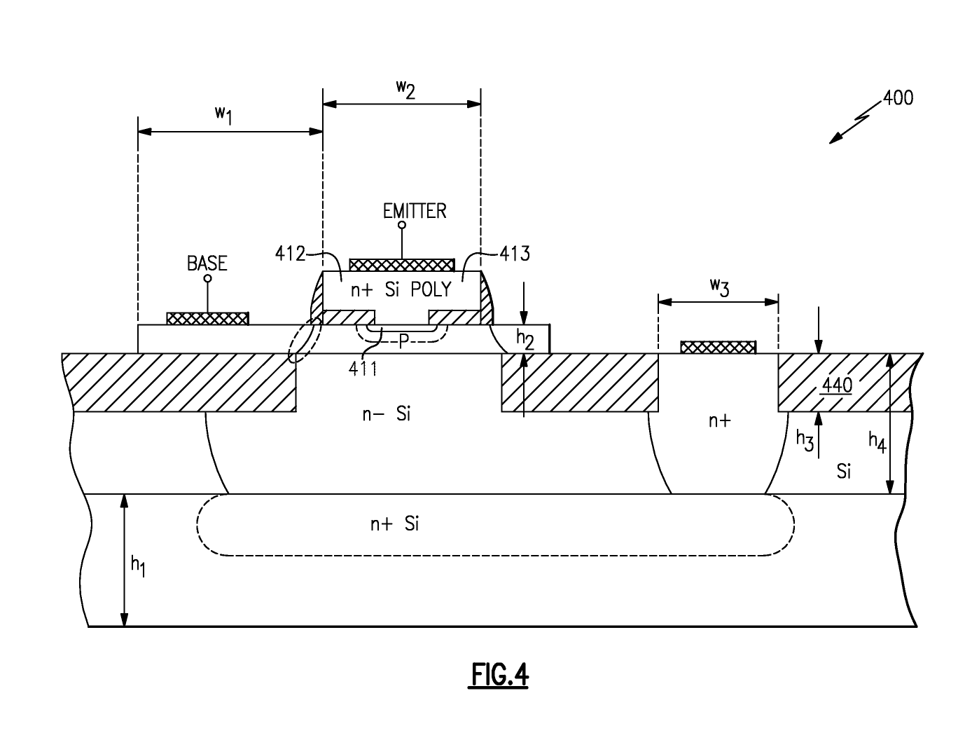

FIG. 4 illustrates a cross-sectional view of an embodiment of a bipolar transistor that may have similar dimensions and/or characteristics to one or more of the devices illustrated in FIGS. 1-3. The various dimensions illustrated in FIG. 4 are not necessarily drawn to scale, and are provided for discussion purposes. The width of the portion of the base that extends laterally beyond the emitter is designated by the reference number w1. As shown, the base may include a metal base contact deposited thereon. In certain embodiments, the width w₁ is between about μm and 2 μm. w₂ designates the width of the emitter-poly. As shown, the emitter may have a metal emitter contact deposited thereon for electrical coupling with the emitter. In certain embodiments the value of w₂ is between about 0.3 μm and 2.0 μm. For example, the width of the polysilicon portion 412 and/or 413 may be between about 0.1 μm and 0.5 μm, and the width of the monosilicon portion 411 may be between about 0.1 μm and 1.0 μm. The width w₃ corresponds to the width of the collector contact region, which may have a metal contact layer disposed thereon. The value of w₃ may be between about 0.2 μm and 2.0 μm, for example.

The thickness of the bulk substrate at one or more points is designated by h₁, which extends between the back of the wafer and the bulk silicon/epitaxial silicon transition. As described, the bulk silicon substrate may include a highly-doped subcollector portion. The value of h₁ may be between about 50 μm and 800 μm in certain embodiments. The height of the base layer is represented by h₂. In certain embodiments, the value of h₂ is between about 500 Å and 10,000 Å. The height h3 represents the thickness of oxide layer 440. The oxide layer may provide shallow trench isolation between portions of the device 400. In certain embodiments, the value of h₃ is between about 0.2 μm and 1.0 μm. Furthermore, the height h₄ represents the height of the epitaxial silicon layer grown above the bulk silicon layer. In certain embodiments, h₄ is between about 0.4 μm and 1.5 μm. The epitaxial silicon layer may include the collector portion.

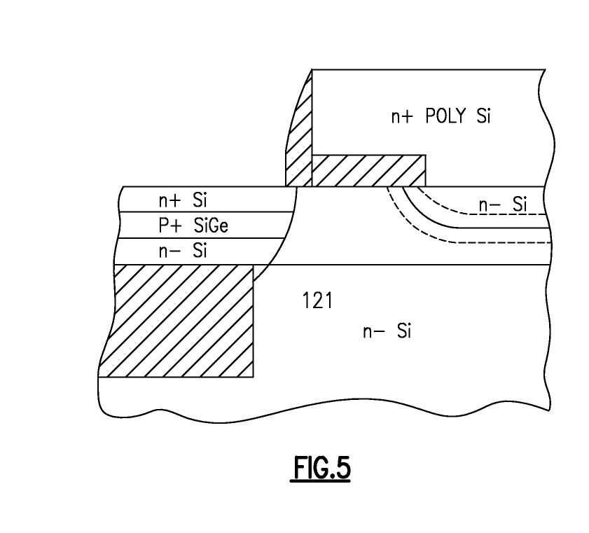

FIG. 5 illustrates a region similar to that illustrated in FIG. 2, wherein the transistor is a SiGe HBT. Principles disclosed herein in the context of silicon BJTs may also be applicable to SiGe or other HBT devices. The structure of FIG. 5 is provided for example only. The NPN embodiment of FIG. 5 may include a lightly-doped n-type silicon lower base layer and a highly-doped n-type silicon upper base layer, with a highly-doped p-type SiGe layer disposed between the two silicon layers. As with other semiconductor embodiments described herein, although shown as an NPN device, the device of FIG. 5 may be a PNP device in certain embodiments.

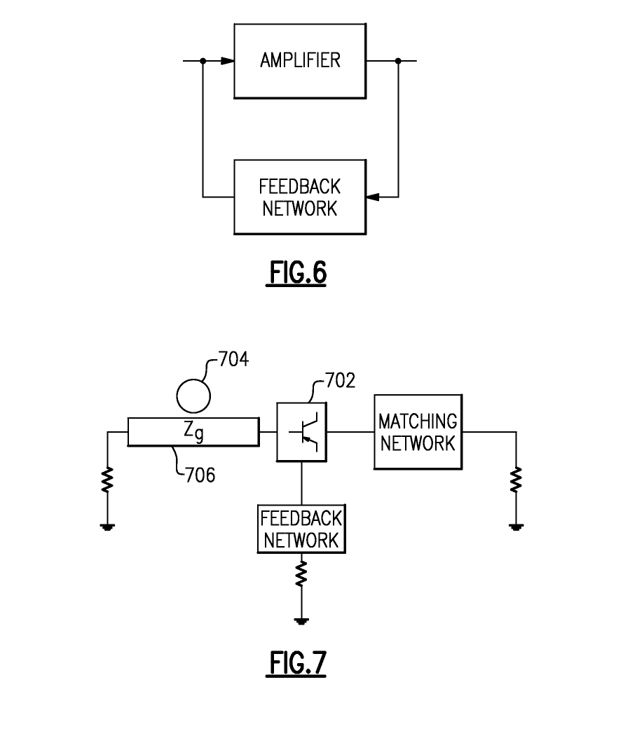

Bipolar amplifiers described herein may serve as components in larger devices or systems. For example, one application of bipolar amplifiers in which phase noise reduction may be a concern is in electronic oscillators comprising one or more bipolar devices, such as linear oscillators. Oscillators configured to operate below radio frequencies, for example, may benefit from 1/f noise reduction due to the greater effect of such noise at lower frequencies. FIG. 6 illustrates a diagram of a feedback linear oscillator comprising an amplifier and feedback network. The amplifier, which may comprise a bipolar transistor constructed with phase noise-reduction principles described herein, is connected in a feedback loop with its output fed back into its input through a frequency-selective filter. Therefore, signal travelling around the loop is filtered to a particular frequency and amplified to provide the output signal. The feedback network may utilize any suitable filter for frequency selection. For example, the feedback network may include one or more of the following: an RC circuit, an LC circuit, a crystal resonator, a dielectric resonator, or other frequency-selective element.

Crystal oscillators, DRO's, and surface acoustic wave oscillators are examples of high-Q oscillators. Utilization of such oscillators may be advantageous in certain embodiments, as they may be less susceptible to certain types of phase noise than lower-Q devices. FIG. 7 provides a schematic diagram of an example embodiment of a dielectric resonator oscillator (DRO) circuit. As shown, a DRO may include an amplifier 702, such as a bipolar device, having a transmission line 706 coupling signals to the amplifier, wherein a dielectric resonator is disposed in proximity to the transmission line. DROs are generally characterized by relatively low phase noise, compact size, frequency stability with temperature, ease of integration with other hybrid MIC circuitries, simple construction and the ability to withstand harsh environments. These characteristics can make DROs a desirable design choice for fundamental oscillators.

The active amplifier device 702 should be capable of providing useful gain at the desired frequency. The circuit further includes a feedback circuit to help achieve a stability factor of the active device with the feedback circuit that is less than unity with enough margin. The impedance of the transmission line Z_{g} may be optimized with the parameters in the feedback circuit and in the matching network. Furthermore, the electrical spacing of the dielectric resonator 704 may likewise be optimized. The characteristic impedance of the output transmission line, Zg, may be selected to be, for example, about 50 ohms, or some other value. While DROs and certain other oscillator types may generally provide high-Q performance, as discussed above, costs associated with dielectric resonators can be prohibitive or deterrent in certain RF applications.

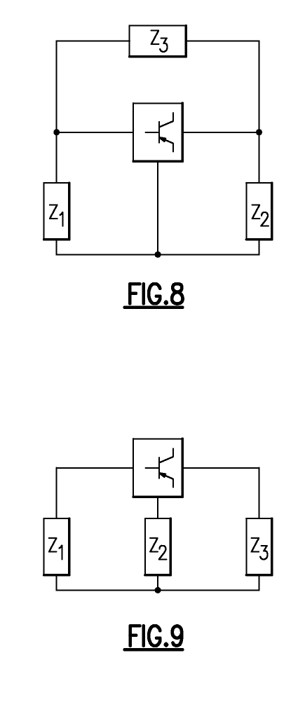

FIGS. 8 and 9 illustrate example electronic oscillator topologies that may correspond to oscillators incorporating active elements constructed with phase noise reduction characteristics described herein. Various different topologies are available for electronic oscillators. Two such topologies used are parallel feedback and series feedback, as shown in FIGS. 8 and 9, respectively. A parallel feedback oscillator, as shown in FIG. 8, may be based on a transmission amplifier. In the case of the parallel feedback, it may be necessary or desirable to match the active element to achieve a sufficient margin of gain in the relevant frequency range. However, by increasing the open loop gain, the open loop phase fluctuations may likewise increase, thereby potentially degrading the phase noise performance of the oscillator. The series feedback oscillator may be based on a reflection amplifier. In certain embodiments, optimal tradeoff between high gain and low phase noise can be achieved with the series feedback topology. Therefore, certain embodiments disclosed herein may incorporate series feedback topology.

In certain embodiments, an oscillator is a component of an RF module of a device having wireless transmission and/or reception functionality. For example, oscillator signals may be provided to a mixer, which mixes the signals with a carrier frequency, such as at microwave frequencies for RF transmission. Such oscillators may be low-frequency oscillators that provide signals below 20 Hz, for example. In certain embodiments, an oscillator according to one or more embodiments disclosed herein operates around 1 kHz. A signal from such oscillator may be mixed with, for example, a 2.4 GHZ (e.g., for WiFi transmission). Therefore, outputs from the mixer may include components at approximately 2.4001 (2.4GHz+1 KHz), as well as a component at approximately 2.3999 (2.4GHz-1 KHz).

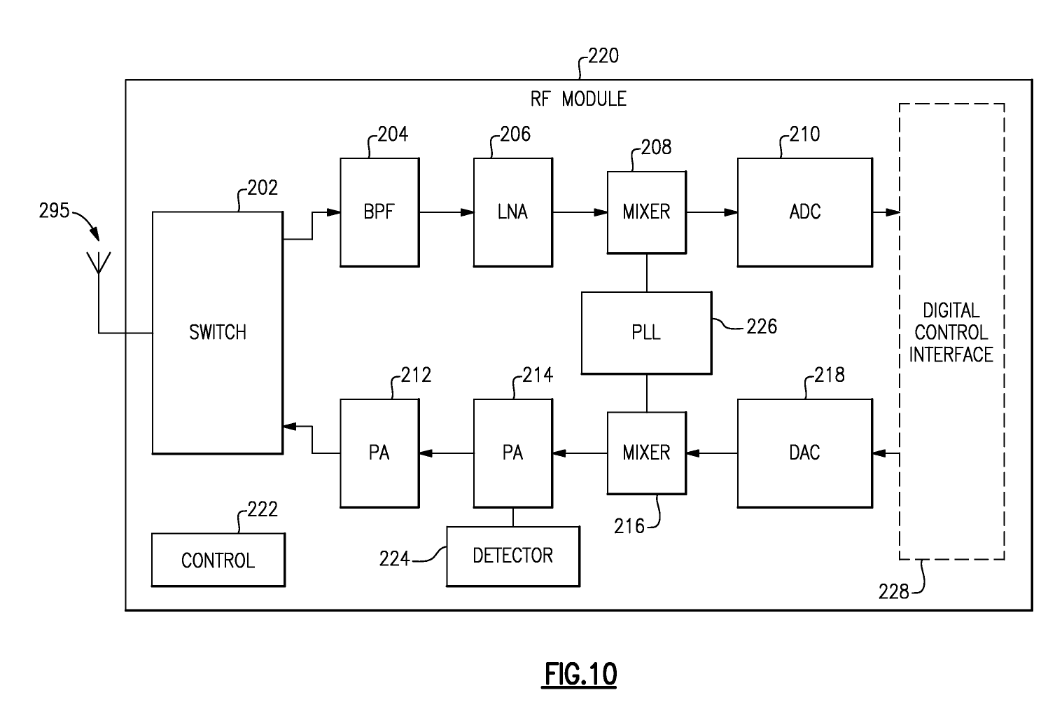

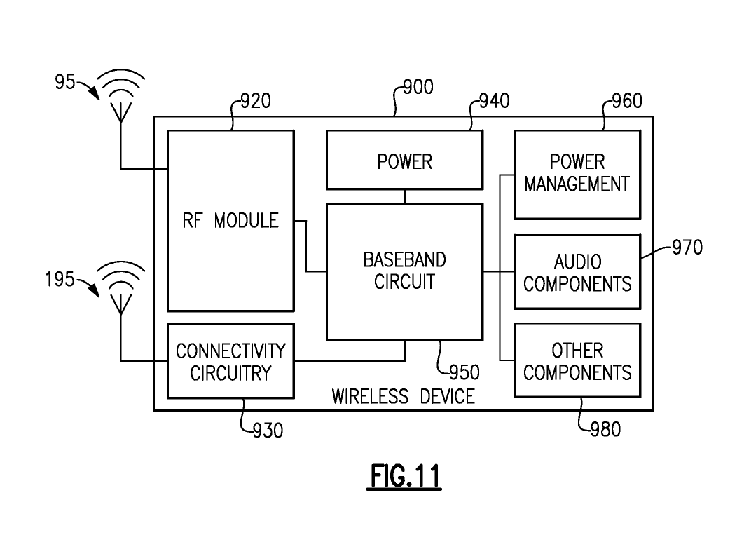

FIG. 10 provides an embodiment of an RF module that may include one or more active devices that incorporate phase noise reduction features described herein. The RF module 220 includes a switch 202 which is connected to an antenna 295. The antenna 295 may receive and/or transmit wireless signals between the RF module 220 and an external source. In certain embodiments, the switch 202 is configured to select a path of propagation for a wireless signal through the switch 202. In certain embodiments, a first configuration of the switch 202 connects a path between the antenna 295 and a receiver portion of the RF module 220. The receiver portion of the RF module may include, for example, a band-pass filter (BPF) 209, which is a device that passes frequencies within a certain range, or band, and rejects or attenuates frequencies outside that range. The BPF 209 may be configured to filter out unwanted spectrum of RF signal corresponding to a desired channel of operation. In certain embodiments, the receiver portion of the RF module includes dual-band functionality, wherein the receiver signal is divided into multiple receiver paths (not shown) corresponding to different channels of operation.

The received signal may be provided from the bandpass filter to a low noise amplifier (LNA) 206, which serves to amplify the received signal. The LNA 206, which is an electronic amplifier used to amplify possibly very weak signals may be desirable in order to amplify signals captured by the antenna 295, which can be relatively weak. Although the LNA is depicted as being disposed at a point in the receiver path following the BPF 204, the LNA 206 may be disposed at any suitable position in the receiver path. The LNA 206 may be disposed following the BPF 204 in order to avoid amplification of out-of-band signals. In certain embodiments, the LNA 206 is disposed relatively close to the antenna 295 in order to reduce feedline losses that may otherwise reduce receiver sensitivity.

The signal may be provided from the LNA 206 to a mixer 208, and further to an analog-to-digital converter (ADC) 210. The mixer 208 is a nonlinear electrical circuit that converts the received RF signal to an intermediate frequency for processing by a baseband module. The mixer 208 may be configured to create new frequencies from two signals applied to it, such as the received RF signal, and a signal from a phase-locked loop (PLL) module 226, such as a signal generated by a local oscillator that operates in connection with the PLL 226. The mixer 208 may comprise a variable frequency oscillator and/or a phase detector. The oscillator may include one or more active devices configured to reduce phase noise according to one or more embodiments disclosed herein. In certain embodiments, the mixer circuit compares the phase of the input signal with the phase of the signal derived from its output oscillator and adjusts the frequency of its oscillator to keep the phases matched. The signal from the phase detector can be used to control the oscillator in a feedback loop.

The ADC 210 may be desirable for converting the received RF signal to a digital signal for baseband processing. The digital signal may be provided by the ADC to one or more components of the wireless device via a digital control interface 228

When the switch 202 is placed in a transmit mode of operation, a path is enabled between the antenna and a transceiver portion of the RF module 220. A signal may be provided to the RF module via the digital control interface 228, such as, from a baseband processor or other module. For example, the signal may be provided to a digital-to-analog converter (DAC) 218, which serves to convert the received signal to an analog signal for transmission by the RF module. The converted analog signal may be passed to a mixer module 216 and further to a power amplifier module 214, which amplifies the signal to be transmitted. The power amplifier may be coupled to a detector which detects a signal power present in the power amplifier module. The signal to be transmitted may pass to a low pass filter (LPF) 212, which filters out noise and other undesired frequencies from the transmitted signal. In certain embodiments, the LPF 212 is disposed before the PA 214 in the transmitter path in order to avoid amplification of undesired signals. The signal is transmitted by the RF module 220 using the antenna 295.

The RF module 220 may further comprise of one or more control modules 222 for controlling the operation of the various elements of the RF module. The control module 222 may comprise control functionality, such as band-selection logic, switch control logic, and/or amplifier enablement logic.

FIG. 11 illustrates an embodiment of a wireless device 900 in accordance with one or more aspects of the present disclosure. Applications of the present disclosure are not limited to wireless devices and can be applied to any type of electronic device including RF front-end circuitry. The application of expanded distance between polysilicon and single silicon base regions in active devices associated with one or more components of the wireless device 900 may provide reduced phase noise in certain embodiments. The wireless device 900 can include an RF module 920. In certain embodiments, the RF module 920 includes multiple signal-processing components. For example, the RF module 920 may include discrete components for amplification and/or filtering of signals in compliance with one or more wireless data transmission standards, such as GSM, WCDMA, LTE, EDGE, WiFi, etc.

The RF module 920 may include transceiver circuitry. In certain embodiments, the RF module 920 comprises a plurality of transceiver circuits, such as to accommodate operation with respect to signals conforming to one or more different wireless data communication standards. Transceiver circuitry may serve as a signal source that determines or sets a mode of operation of one or more components of the RF module 920. Alternatively, or in addition, a baseband circuit 950, or one or more other components that are capable of providing one or more signals to the RF module 920 may serve as a signal source provided to the RF module 920. In certain embodiments, the RF module 920 can include a digital to analog convertor (DAC), a user interface processor, and/or an analog to digital convertor (ADC), among possibly other things.

The RF module 920 is electrically coupled to the baseband circuit 950, which processes radio functions associated with signals received and/or transmitted by one or more antennas (e.g., 95, 195). Such functions may include, for example, signal modulation, encoding, radio frequency shifting, or other function. The baseband circuit 950 may operate in conjunction with a real-time operating system in order to accommodate timing-dependent functionality. In certain embodiments, the baseband circuit 950 includes, or is connected to, a central processor. For example, the baseband circuit 950 and central processor may be combined (e.g., part of a single integrated circuit), or may be separate modules or devices.

The baseband circuit 950 is connected, either directly or indirectly, to a memory module 940, which contains one or more volatile and/or non-volatile memory/data storage, devices or media. Examples of types of storage devices that may be included in the memory module 940 include Flash memory, such as NAND Flash, DDR SDRAM, Mobile DDR SRAM, or any other suitable type of memory, including magnetic media, such as a hard disk drive. Furthermore, the amount of storage included in memory module 940 may vary based on one or more conditions, factors, or design preferences. For example, memory module 940 may contain approximately 256 MB, or any other suitable amount, such as 1 GB or more. The amount of memory included in the wireless device 900 may depend on factors such as, for example, cost, physical space allocation, processing speed, etc.

The wireless device 900 includes a power management module 960. The power management module 960 includes, among possibly other things, a battery or other power source. For example, power management module may include one or more lithium-ion batteries. In addition, the power management module 960 may include a controller module for management of power flow from the power source to one or more regions of the wireless device 900. Although the power management module 960 may be described herein as including a power source in addition to a power management controller, the terms “power source” and “power management,” as used herein, may refer to either power provision, power management, or both, or any other power-related device or functionality.

The wireless device 900 may include one or more audio components 970. Example components may include one or more speakers, earpieces, headset jacks, and/or other audio components. Furthermore, the audio component module 970 may include audio compression and/or decompression circuitry (i.e., “codec”). An audio codec may be included for encoding signals for transmission, storage or encryption, or for decoding for playback or editing, among possibly other things.

The wireless device 900 includes connectivity circuitry 930 comprising one or more devices for use in receipt and/or processing of data from one or more outside sources. To such end, the connectivity circuitry 930 may be connected to one or more antennas 195. For example, connectivity circuitry 930 may include one or more power amplifier devices, each of which is connected to an antenna. The antenna 195 may be used for data communication in compliance with one or more communication protocols, such as WiFi (i.e., compliant with one or more of the IEEE 802.99 family of standards) or Bluetooth, for example. Multiple antennas and/or power amplifiers may be desirable to accommodate transmission/reception of signals compliant with different wireless communications protocols. Among possibly other things, the connectivity circuitry 930 may include a Global Positioning System (GPS) receiver.

The connectivity circuitry 930 may include one or more other communication portals or devices. For example, the wireless device 900 may include physical slots, or ports, for engaging with Universal Serial Bus (USB), Mini USB, Micro USB, Secure Digital (SD), miniSD, microSD, subscriber identification module (SIM), or other types of devices through a data-communication channel.

The wireless device 900 includes one or more additional components 980. Examples of such components may include a display, such as an LCD display. The display may be a touchscreen display. Furthermore, the wireless device 900 may include a display controller, which may be separate from, or integrated with, the baseband circuit 950 and/or a separate central processor. Other example components that may be included in the wireless device 900 may include one or more cameras (e.g., cameras having 2 MP, 3.2, MP, 5 MP, 10 MP, or other resolution), compasses, accelerometers, or other functional devices.

The components described above in connection with FIG. 11 and wireless device 900 are provided as examples, and are non-limiting. Moreover, the various illustrated components may be combined into fewer components, or separated into additional components. For example, the baseband circuit 950 can be at least partially combined with the RF module 920. As another example, the RF module 920 can be split into separate receiver and transmitter portions.

While various embodiments of integrated front-end modules have been described, it will be apparent to those of ordinary skill in the art that many more embodiments and implementations are possible. For example, embodiments of integrated FEMs are applicable to different types of wireless communication devices, incorporating various FEM components. In addition, embodiments of integrated FEMs are applicable to systems where compact, high-performance design is desired. Some of the embodiments described herein can be utilized in connection with wireless devices such as mobile phones. However, one or more features described herein can be used for any other systems or apparatus that utilize of RF signals.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A semiconductor die comprising:
an epitaxial collector layer having an upper surface that lies in a first plane and an active collector region disposed adjacent said upper surface;
first and second oxide trenches disposed adjacent said upper surface on opposite sides of said active collector region;
a base layer including a monosilicon portion disposed adjacent said active collector region, first and second polysilicon portions disposed adjacent said first and second oxide trenches, respectively, and a polysilicon/monosilicon boundary portion disposed between said monosilicon portion and said first polysilicon portion;
an emitter layer disposed at least partially adjacent said base layer and including a window portion in direct contact with said monosilicon portion of said base layer; and
first and second emitter oxide portions in direct physical contact with said base layer, each disposed on opposite sides of said emitter window portion, said first and second emitter oxide layers abutting said emitter window at first and second emitter-oxide interfaces, respectively, such that a first lateral distance between said first oxide trench and said first emitter-oxide interface is greater than a second lateral distance between said second oxide trench and said second emitter oxide interface.

2. The semiconductor die of claim 1 wherein a ratio of said first lateral distance to said second lateral distance is greater than or equal to approximately 1.5:1.

3. The semiconductor die of claim 1 wherein said first lateral distance is greater than approximately 0.4 μm.

4. The semiconductor die of claim 1 wherein said first lateral distance is approximately 0.5 μm.

5. The semiconductor die of claim 1 wherein a third lateral distance between said polysilicon/monosilicon boundary portion of said base layer and a depletion region of said base layer is greater than approximately 0.05 μm.

6. The semiconductor die of claim 1 wherein a third lateral distance between said polysilicon/monosilicon boundary portion of said base layer and a depletion region of said base layer is approximately 0.1 μm.

7. The semiconductor die of claim 1 wherein a width of said first emitter oxide portion is greater than approximately 0.2 μm.

8. The semiconductor die of claim 1 wherein a width of said first emitter oxide portion is approximately 0.3 μm.

9. The semiconductor die of claim 1 wherein a width of said first emitter oxide portion is between approximately 0.2-0.4 μm.

10. A method of manufacturing a semiconductor die comprising:
disposing an epitaxial collector layer on a bulk silicon substrate, the epitaxial collector layer having an upper surface that lies in a first plane and an active collector region disposed adjacent said upper surface;
forming first and second oxide trenches adjacent said upper surface on opposite sides of said active collector region;
disposing a monosilicon base portion adjacent said active collector region;
disposing first and second polysilicon portions adjacent said first and second oxide trenches, respectively, such that a polysilicon/monosilicon boundary portion is formed between said monosilicon portion and said first polysilicon portion;
disposing an emitter layer at least partially adjacent said base layer, said emitter layer including a window portion in direct contact with said monosilicon portion of said base layer; and
forming first and second emitter oxide portions in direct physical contact with said base layer on opposite sides of said emitter window portion, said first and second emitter oxide layers abutting said emitter window at first and second emitter-oxide interfaces, respectively, such that a first lateral distance between said first oxide trench and said first emitter-oxide interface is greater than a second lateral distance between said second oxide trench and said second emitter oxide interface.

11. The method of claim 10 wherein a ratio of said first lateral distance to said second lateral distance is greater than or equal to approximately 1.5:1.

12. The method of claim 10 wherein said first lateral distance is greater than approximately 0.4 μm.

13. The method of claim 10 wherein said first lateral distance is approximately 0.5 μm.

14. The method of claim 10 wherein a third lateral distance between said polysilicon/monosilicon boundary portion of said base layer and a depletion region of said base layer is greater than approximately 0.05 μm.

15. The method of claim 10 wherein a third lateral distance between said polysilicon/monosilicon boundary portion of said base layer and a depletion region of said base layer is approximately 0.1 μm.

16. The method of claim 10 wherein a width of said first emitter oxide portion is greater than approximately 0.2 μm.

17. The method of claim 10 wherein a width of said first emitter oxide portion is approximately 0.3 μm.

18. The method of claim 10 wherein a width of said first emitter oxide portion is between approximately 0.2-0.4 μm.
